(19) United States
(12) Patent Application Publication
(10) Pub. No.: US 2007/0098892 A1
(43) Pub. Date: May 3, 2007

(54) METHOD OF FORMING A LAYER AND METHOD OF MANUFACTURING A CAPACITOR USING THE SAME

(75) Inventors: Eun-Ae CHUNG, Gyeonggi-do (KR); Kyoung-Ryul YOON, Gyeonggi-do (KR); Ki-Vin IM, Gyeonggi-do (KR); Jae-Hyun YEO, Gyeonggi-do (KR); Sung-Tae KIM, Seoul (KR); Young-Sun KIM, Gyeonggi-do (KR); Young-Geun PARK, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/468,932

(22) Filed: Aug. 31, 2006

(30) Foreign Application Priority Data
Aug. 31, 2005 (KR) 2005-80590

(51) Int. Cl. C23C 16/00; B05D 3/02; B05D 5/12

(52) U.S. Cl. 427/248.1; 427/372.2; 427/79

(57) ABSTRACT

In a method of forming a layer and a method of manufacturing a capacitor using the same, a preliminary zirconium oxide film is formed on a substrate by introducing a first reactant including a zirconium precursor, and a first oxidant onto the substrate. A thermal treatment is performed on the preliminary zirconium oxide film to form a first zirconium oxide film having a dense and crystalline structure. An aluminum oxide film is formed on the first zirconium oxide film by introducing a second reactant including an aluminum precursor, and a second oxidant onto the substrate. The thermally-treated layer including the first zirconium oxide film and the aluminum oxide film may form a dielectric layer of a capacitor.

### CROSS-REFERENCE TO RELATED APPLICATIONS

This application claims priority under 35 USC § 119 to Korean Patent Application No. 2005-80590 filed on Aug. 31, 2005, the contents of which are herein incorporated by reference in their entireties.

### BACKGROUND OF THE INVENTION

1. Field of the Invention

The present invention relates to a method of forming a high-dielectric-constant layer in a semiconductor device and a method of manufacturing a capacitor using the same. More particularly, the present invention relates to a method of forming a multilayer-dielectric layer having a zirconium oxide film, and a method of manufacturing a capacitor using the same.

2. Description of the Related Art

Recently, a thin film, such as a gate insulation layer of a metal oxide semiconductor (MOS) transistor or a dielectric layer of a capacitor, has been formed using a material having a relatively high dielectric constant (hereinafter, referred to as “a high-k material”). The thin film including the high-k material may have a relatively thin equivalent oxide thickness (EOT) and may sufficiently prevent a leakage current from being generated between a gate electrode and a channel region, or between lower and upper electrodes of a capacitor. Examples of the high-k material may include zirconium oxide, hafnium oxide, aluminum oxide, tantalum oxide, praseodymium oxide, lanthanum oxide, etc.

In order to improve operational characteristics of a semiconductor device, a multi-layered thin film or an alloy thin film, which contains zirconium oxide, has been developed and applied to the dielectric layer of the capacitor or the gate insulation layer of the MOS transistor.

The multi-layered thin film or the alloy thin film containing zirconium oxide, which is used as a dielectric layer of a capacitor, is disclosed in Korean Patent No. 456,554, Japanese Laid-Open Patent Publication No. 2004-214304, etc. Particularly, Korean Patent No. 456,554 discloses a dielectric layer having a multi-layered structure including a zirconium oxide thin film and an aluminum oxide thin film, which are sequentially formed.

However, when the dielectric layer of the capacitor has a double-layered structure including a zirconium oxide film and an aluminum oxide film, or a triple-layered structure including a first zirconium oxide film, an aluminum oxide film and a second zirconium oxide film, a leakage current can be frequently generated at a relatively low voltage applied to the capacitor. When the aluminum oxide film is formed on the zirconium oxide film, a lower electrode positioned under the zirconium oxide film can be oxidized. That is, since the zirconium oxide film has a relatively sparse and non-crystalline structure, an oxidizing agent such as oxygen gas can easily penetrate into the zirconium oxide film to oxidize the lower electrode beneath the zirconium oxide film while the aluminum oxide film is formed on the zirconium oxide film.

As described above, the multi-layered thin film or the alloy thin film containing zirconium oxide has been employed as the dielectric layer of the capacitor to improve the operational characteristics of the capacitor. However, structural defects of the zirconium oxide film frequently cause a deterioration of the lower electrode.

Accordingly, a need remains for a better way to make high-k dielectric layers and capacitors.

### SUMMARY OF THE INVENTION

Example embodiments of the present invention provide methods of forming a layer having a dense and crystalline structure.

Example embodiments of the present invention provide methods of manufacturing a capacitor including the above-mentioned layer as a dielectric layer.

According to one aspect of the present invention, there is provided a method of forming a layer. In the method of forming the layer, a preliminary zirconium oxide film is formed on a substrate by introducing a first reactant including a zirconium precursor and a first oxidant onto the substrate. Then, a thermal treatment is performed on the preliminary zirconium oxide film to form a first zirconium oxide film having a dense and crystalline structure. An aluminum oxide film is formed on the first zirconium oxide film by introducing a second reactant including an aluminum precursor and a second oxidant onto the substrate.

The first zirconium oxide film having the dense and crystalline structure is formed by a thermal treatment. Accordingly, the first zirconium oxide film having the dense and crystalline structure can prevent or reduce an oxidation of a lower structure formed below or beneath the first zirconium oxide film while the aluminum oxide film is formed on the first zirconium oxide film.

In an example embodiment of the present invention, the thermal treatment may be performed at a temperature of about 400° C. to about 700° C. under an atmosphere including an inactive gas, an oxygen gas or a combination thereof.

In an example embodiment of the present invention, the first reactant may include tetrakis (ethylmethylamino) zirconium, zirconium butyl oxide or a mixture thereof.

In an example embodiment of the present invention, the second reactant may include trimethyl aluminum, aluminum butyl oxide, or a mixture thereof.

In an example embodiment of the present invention, the first and the second oxidants may include ozone, oxygen, water vapor, hydrogen peroxide, oxygen plasma, oxygen remote plasma, nitrous oxide, nitrous oxide plasma, methanol, ethanol or a combination thereof.

In an example embodiment of the present invention, the preliminary zirconium oxide film and the aluminum oxide film may be formed by an atomic layer deposition (ALD) process, respectively.

In an example embodiment of the present invention, a second zirconium oxide film may be formed on the aluminum oxide film by introducing a third reactant including a zirconium precursor, and a third oxidant onto the substrate.

In an example embodiment of the present invention, the second zirconium oxide film may be formed by an ALD process.

According to another aspect of the present invention, there is provided a method of manufacturing a capacitor. In the method of manufacturing the capacitor, a lower electrode is formed on a substrate. A dielectric layer having a multi-layered structure is formed on the lower electrode. Particularly, a preliminary zirconium oxide film is formed on the lower electrode by introducing a first reactant including a zirconium precursor and a first oxidant onto the lower electrode. A thermal treatment is performed on the preliminary zirconium oxide film to form a first zirconium oxide film having a dense and crystalline structure, and then an aluminum oxide film is formed on the first zirconium oxide film by introducing a second reactant including an aluminum precursor and a second oxidant onto the substrate. Accordingly, the dielectric layer including the first zirconium oxide film having a dense and crystalline structure and the aluminum oxide film is formed on the lower electrode. Subsequently, an upper electrode is formed on the dielectric layer. As a result, the capacitor including the lower electrode, the dielectric layer and the upper electrode is manufactured on the substrate.

The first zirconium oxide film having the dense and crystalline structure is formed by a thermal treatment. Accordingly, the first zirconium oxide film can prevent or reduce an oxidation of the lower electrode formed beneath the first zirconium oxide film while the aluminum oxide film is formed on the first zirconium oxide film. Therefore, a deterioration of the lower electrode can be prevented or reduced, and a capacitor including the dielectric layer with an enhanced dielectric constant can be easily manufactured.

In an example embodiment of the present invention, each of the lower electrode and the upper electrode may include polysilicon, a metal, a metal nitride or a combination thereof.

In an example embodiment of the present invention, the thermal treatment may be performed at a temperature of about 400° C. to about 700° C. under an atmosphere including an inactive gas, an oxygen gas or a combination thereof.

In an example embodiment of the present invention, the first reactant may include tetrakis (ethylmethylamino) zirconium, zirconium butyl oxide or a mixture thereof, the second reactant may include trimethyl aluminum, aluminum butyl oxide or a mixture thereof, and each of the first and the second oxidants may include ozone, oxygen, water vapor, hydrogen peroxide, oxygen plasma, oxygen remote plasma, nitrous oxide, nitrous oxide plasma, methanol, ethanol or a combination thereof.

In an example embodiment of the present invention, the preliminary zirconium oxide film and the aluminum oxide film may be formed by an ALD process, respectively.

In an example embodiment of the present invention, the preliminary zirconium oxide film may have a thickness of about 10 Å to about 150 Å and the aluminum oxide film may have a thickness of about 1 Å to about 30 Å.

In an example embodiment of the present invention, a second zirconium oxide film may be formed on the aluminum oxide film by introducing a third oxidant and a third reactant including a zirconium precursor onto the substrate. Accordingly, the dielectric layer including the first zirconium oxide film, the aluminum oxide film and the second zirconium oxide film may be formed on the lower electrode.

In an example embodiment of the present invention, the second zirconium oxide film may be formed by an ALD process.

In an example embodiment of the present invention, the second zirconium oxide film may have a thickness of about 10 Å to about 150 Å.

According to still another aspect of the present invention, there is provided a method of forming a layer. In the method of manufacturing the layer, a preliminary metal oxide film is formed on a substrate by introducing a first oxidant and a first reactant including a first metal precursor onto the substrate. A thermal treatment is performed on the preliminary metal oxide film to form a first metal oxide film having a dense and crystalline structure. A second metal oxide film is formed on the first metal oxide film by introducing a second oxidant and a second reactant including a second metal precursor onto the substrate.

In an example embodiment of the present invention, the first and the second metal oxide films may include metal oxides different from each other. Examples of the metal oxide may include zirconium oxide, aluminum oxide, barium strontium oxide, strontium oxide, hafnium oxide, tantalum oxide, praseodymium oxide, titanium oxide, lanthanum oxide and the like.

In an example embodiment of the present invention, the thermal treatment may be performed at a temperature of about 400° C. to about 700° C. under an atmosphere including an inactive gas, an oxygen gas or a combination thereof.

According to the present invention, a dielectric layer having a multi-layered structure may be formed using a thermal treatment. Particularly, a zirconium oxide film having a dense and crystalline structure may be formed by the thermal treatment. Therefore, a deterioration of a lower electrode positioned under the dielectric layer may be prevented or reduced, and a generation of a leakage current from the dielectric layer may be suppressed. Furthermore, the dielectric layer having a sufficiently thin equivalent oxide thickness (EOT) may be formed by the thermal treatment to enhance an integration degree of a semiconductor device.

### BRIEF DESCRIPTION OF THE DRAWINGS

The foregoing and other features and advantages of the present invention will become more readily apparent by describing in detailed example embodiments thereof with reference to the accompanying drawings, in which:

FIGS. 1A to 1J are cross-sectional views illustrating a method of forming a layer in accordance with an example embodiment of the present invention;

FIG. 2 is a cross-sectional view illustrating a layer formed by a method in accordance with an example embodiment of the present invention;

FIGS. 3A to 3E are cross-sectional views illustrating a method of manufacturing a capacitor in accordance with an example embodiment of the present invention; and

FIGS. 4A and 4B are graphs showing leakage current characteristics of a capacitor of a semiconductor device manufactured by a method in an example embodiment of the present invention.

### DESCRIPTION OF EXAMPLE EMBODIMENTS

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “over,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “over,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-sectional illustrations that are schematic illustrations of idealized example embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary or step change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this present invention belongs. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

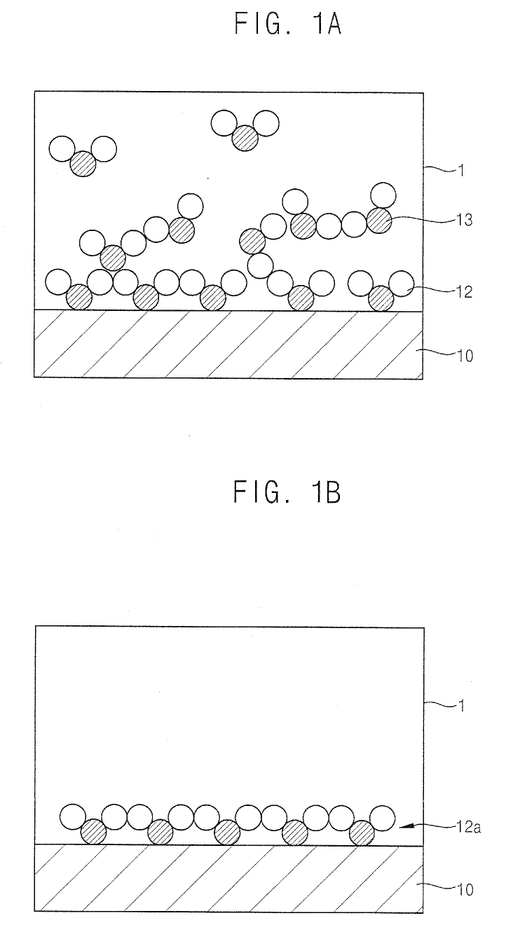

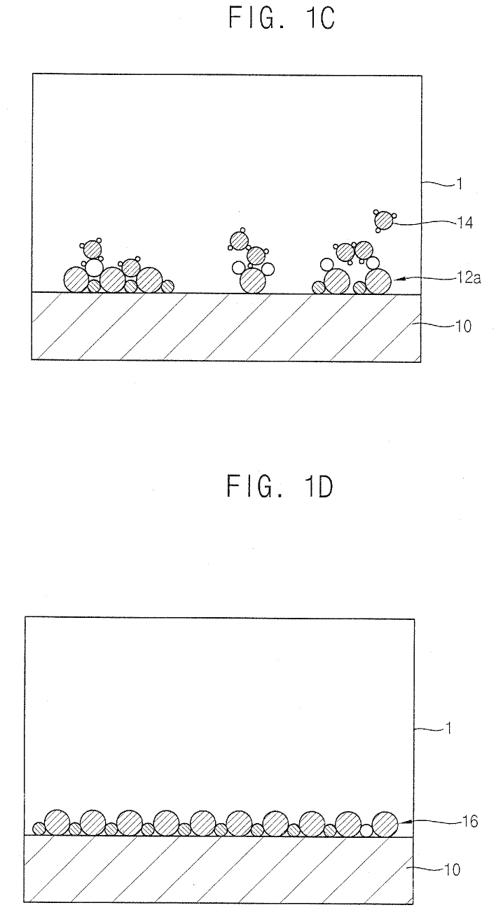

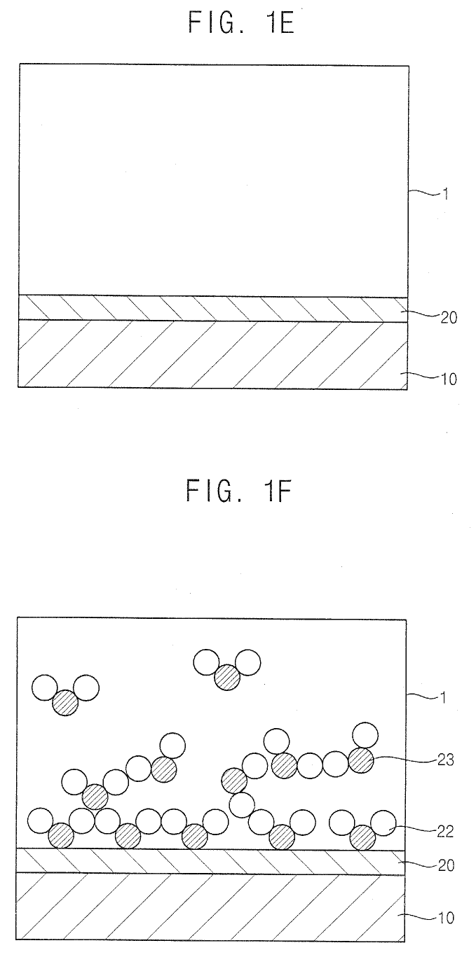

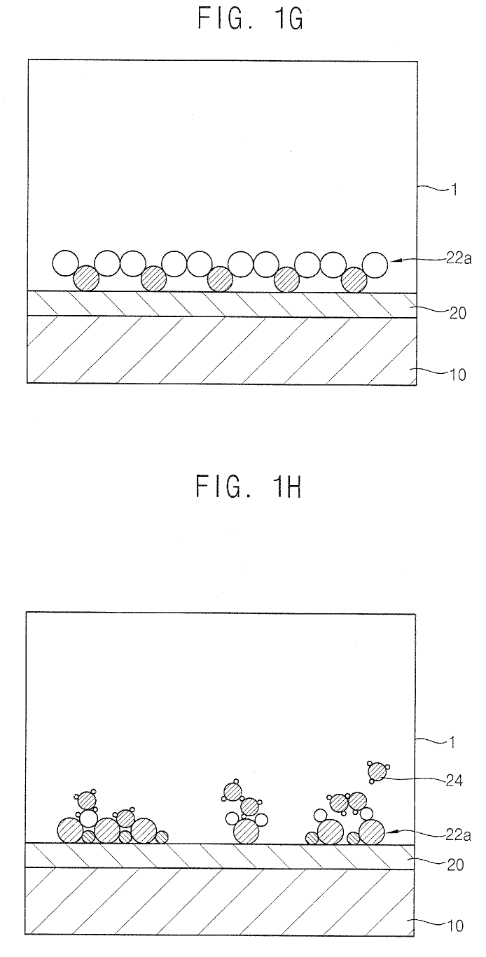

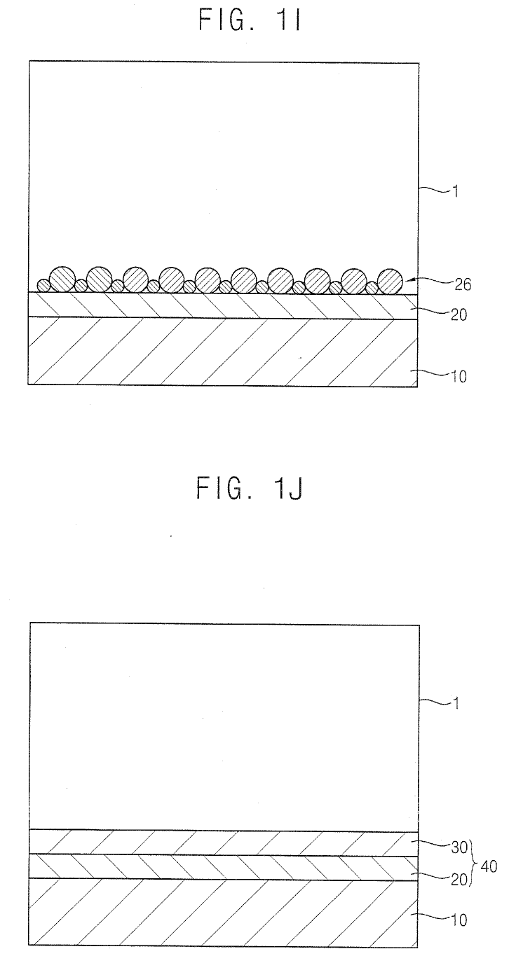

FIGS. 1A to 1J are cross-sectional views illustrating a method of forming a layer in accordance with an example embodiment of the present invention.

Referring to FIG. 1A, a substrate 10 is positioned in a chamber 1. When the chamber 1 has a temperature below about 200° C., a reactant introduced into the chamber 1 may have a poor reactivity, which is disadvantageous. In addition, when the chamber 1 has a temperature above about 400° C., a layer formed on the substrate 10 may be disadvantageously crystallized. In an example embodiment of the present invention, the layer may be formed by an atomic layer deposition (ALD) process. When the layer is formed at a temperature above about 400° C. by the ALD process, the layer may have film characteristics formed by a chemical vapor deposition (CVD) process, instead of those of the ALD process. Therefore, the chamber 1 may have a temperature of about 200° C. to about 400° C., and advantageously a temperature of about 300° C. When the chamber 1 has the temperature of about 300° C., the ALD process may be appropriately carried out so that the layer may have the film characteristics of the ALD process.

When the chamber 1 has an inner pressure lower than about 0.1 Torr, the reactant introduced into the chamber 1 may have a poor reactivity. In addition, when the chamber 1 has the inner pressure higher than about 3.0 Torr, processing conditions may not be easily controlled. Therefore, the inner pressure of the chamber 1 may be advantageously in a range of about 0.1 to about 3.0 Torr.

A first reactant is discharged onto the substrate 10, which is positioned in the chamber 1 having the above-mentioned temperature and inner pressure. Here, the first reactant may be supplied in a gas phase using a phase changer such as a bubbler.

The first reactant may include a precursor for depositing zirconium oxide. Examples of the first reactant may include tetrakis (ethylmethylamino) zirconium (Zr[N(CH3)(C2H5)]4; TEMAZ), zirconium butyl oxide (Zr(O-tBu)4) and the like. These can be used alone or in a combination thereof. In an example embodiment of the present invention, the first reactant may include TEMAZ. The first reactant may be discharged onto the substrate 10 for about 0.5 to about 3 seconds.

In one example embodiment of the present invention, the first reactant may include a zirconium precursor for depositing zirconium oxide. In another example embodiment of the present invention, the first reactant may include a barium precursor, a strontium precursor and/or a titanium precursor for depositing barium strontium titanium oxide (BST), strontium titanium oxide (STO) or titanium oxide. Particularly, examples of the barium precursor that may be used for depositing BST may include Ba(METHD)2, Ba(THD)2 and the like. Examples of the strontium precursor that may be used for depositing BST or STO may include Sr(METHD)2, Sr(THD)2, etc. Examples of the titanium precursor that may be used for depositing BST or STO may include Ti(THD)2(Oi-Pr)2 and the like. In addition, examples of the titanium precursor that may be used for depositing titanium oxide may include titanium chloride (TiCl4), tetrakis (ethylmethylamino) titanium (Ti[N(CH3)(C2H5)]4; TEMAT) or titanium butyl oxide (Ti(O-tBu)4), etc.

When the first reactant is discharged onto the substrate 10, a first portion 12 of the first reactant may be chemically absorbed (referred to as “chemisorbed”) onto the substrate 10. In addition, a second portion 13 of the first reactant, which corresponds to a remainder of the first reactant except for the first portion, may be physically absorbed (referred to as “physisorbed”) onto the substrate 10 or may drift in the chamber 1.

Referring to FIG. 1B, a first purge gas is introduced into the chamber 1. The first purge gas may include an inert gas or an inactive gas such as an argon (Ar) gas, a nitrogen (N2) gas and the like. The first purge gas may be provided onto the substrate 10 for about 0.5 to about 20 seconds.

When the first purge gas is introduced around on the substrate 10, the second portion 13 of the first reactant, which is physisorbed onto the substrate and drifts in the chamber 1, may be removed from the substrate 10 and the chamber 1. Therefore, the first portion 12 that is a chemisorbed molecule 12a of the first reactant (e.g., zirconium precursor) may remain on the substrate.

In one example embodiment of the present invention, the second portion 13 of the first reactant that is physisorbed onto the substrate or drifts in the chamber 1 may be removed from the chamber 1 by evacuating the chamber 1 for about 2 to about 10 seconds, instead of introducing the first purge gas. In another example embodiment of the present invention, the second portion 13 may be removed from the chamber 1 by introducing the first purge gas and by evacuating the chamber 1.

Referring to FIG. 1C, a first oxidant 14 is introduced into the chamber 1. Examples of the first oxidant 14 may include ozone (O3), oxygen gas (O2), water vapor (H2O), hydrogen peroxide (H2O2), oxygen plasma, nitrous oxide (N2O), nitrous oxide plasma, oxygen remote plasma, methanol (CH3OH), ethanol (C2H5OH) and the like. These oxidants may be used individually or in a mixture thereof. In an example embodiment of the present invention, the first oxidant 14 may include ozone. The first oxidant 14 may be introduced into the chamber 1 for about 1 to about 7 seconds,

When the first oxidant 14 is introduced around the substrate 10, the first oxidant may be chemically reacted with the chemisorbed molecule 12a of the first reactant (e.g., zirconium precursor) to oxidize the chemisorbed molecule 12a.

Referring to FIG. 1D, a second purge gas is introduced into the chamber 1. Types and/or purge time of the second purge gas may be substantially the same as those of the first purge gas described with reference to FIG. 1B.

When the second purge gas is pumped into the chamber 1, an unreacted portion of the first oxidant 14 may be removed from the chamber 1. As a result, a first solid-state film 16 is formed on the substrate 10. When the first reactant includes a zirconium precursor, the first solid-state film 16 can include zirconium oxide.

Referring to FIG. 1E, the processes described with reference to FIGS. 1A to 1D are repeatedly carried out at least once. As a result, a preliminary metal oxide film including multiple layers of the first solid-state film 16 is formed on the substrate 10. When a zirconium precursor is used as the first reactant, the preliminary metal oxide film can be a zirconium oxide film. For example, the preliminary metal oxide film may have a thickness of about 10 Å to about 150 Å, and advantageously a thickness of about 50 Å to about 90 Å.

In an example embodiment of the present invention, the preliminary metal oxide film may include BST, STO, titanium oxide and the like.

After the preliminary metal oxide film is formed on the substrate 10, a thermal treatment may be performed on the substrate 10.

The thermal treatment may be performed at a temperature of about 300° C. to about 700° C., and advantageously at a temperature of about 400° C. to about 600° C. Furthermore, the thermal treatment may be carried out under an atmosphere including an inactive or inert gas, oxygen gas or a combination thereof. Examples of the inactive gas may include nitrogen gas, argon gas, etc. Alternatively, the thermal treatment may be performed in a vacuum atmosphere.

The thermal treatment can densify and crystallize the preliminary metal oxide film. As a result, the preliminary metal oxide film may be transformed into a first metal oxide film 20 having a dense and crystalline structure.

In an example embodiment of the present invention, the first metal oxide film 20 includes zirconium oxide. When a zirconium oxide film has a dense and crystalline structure, an equivalent oxide thickness (EOT) of the zirconium oxide film may be substantially reduced. Furthermore, when an aluminum oxide film is formed on the zirconium oxide film by an oxidation process performed at a relatively high temperature, the zirconium oxide film having the dense and crystalline structure can effectively prevent an oxidizing agent (e.g., oxygen gas) from penetrating into a lower structure positioned beneath or below the zirconium oxide film. Thus, deterioration of the lower structure can be prevented or suppressed.

Particularly, when a zirconium oxide film having an amorphous structure is formed by an ordinary ALD process, the zirconium oxide film has dangling bonds and/or micropores that may be a passage for oxygen gas. However, when the thermal treatment is carried out on the zirconium oxide film having the amorphous structure, a structure of the zirconium oxide film can be densified and crystallized sufficiently to reduce the passage for oxygen gas in the zirconium oxide film. Therefore, deterioration of the lower structure beneath or below the zirconium oxide film can be prevented while an aluminum oxide film is formed on the zirconium oxide film.

Referring to FIG. 1F, a second reactant is discharged onto the first metal oxide film 20 formed on the substrate 10. Process conditions such as a temperature and a pressure of the chamber 1 may be controlled similarly to those described with reference to FIG. 1A.

In one example embodiment of the present invention, the second reactant may include an aluminum precursor. Examples of the aluminum precursor may include trimethyl aluminum (Al(CH3)3; TMA), aluminum butyl oxide, etc. These can be used alone or in a mixture thereof.

In another example embodiment of the present invention, the second reactant may include a hafnium (Hf) precursor, a tantalum (Ta) precursor, a praseodymium (Pr) precursor, a lanthanum (La) precursor and/or a titanium (Ti) precursor, etc. Examples of the hafnium precursor may include tetrakis (ethylmethylamino) hafnium (Hf[N(C2H5)(CH3)]4; TEMAH), hafnium butyl oxide (Hf(O-tBu)4), etc. Examples of the tantalum precursor may include Ta(OC2H5)5, Ta(Os-Bu)5, Ta(OC2H5)4(acac), etc. Examples of the praseodymium precursor may include Pr(EDMDD)3, Pr(sBuCp)3, etc. Examples of the lanthanum (La) may include La(THD)3, La(EDMDD)3, La(i-PrCp)3, etc.

The second reactant may be discharged onto the first metal oxide film 20 for about 0.5 to about 3.0 seconds. The second reactant may be introduced into the chamber 1 using a phase changer such as a bubbler in the same manner as that of the first reactant.

When the second reactant is deposited on the first metal oxide film 20, a first portion 22 of the second reactant may be chemisorbed onto the first metal oxide film 20, and a second portion 23 of the second reactant, which is a remainder of the second reactant except for the first portion 22, may be physisorbed onto the first portion 22 or may drift in the chamber 1.

Referring to FIG. 1G, a third purge gas is introduced into the chamber 1. Types and/or purge time of the third purge gas may be substantially the same as those of the first purge gas described with reference to FIG. 1B.

When the third purge gas is introduced into the chamber 1, the second portion 23 of the second reactant, which is physisorbed onto the first portion 22 or drifts in the chamber 1, may be removed from the chamber 1. Thus, the first portion 22 that is a chemisorbed molecule 22a of the second reactant may remain on the first metal oxide film 20.

Referring to FIG. 1H, a second oxidant 24 is introduced into the chamber 1. Types and/or introduction time of the second oxidant may be substantially the same as those of the first oxidant described with reference to FIG. 1C.

When the second oxidant 24 is discharged onto the first metal oxide film 20, the second oxidant 24 can be chemically reacted with the chemisorbed molecule 22a of the second reactant to oxidize the chemisorbed molecule 22a.

In an example embodiment of the present invention, the second reactant may include an aluminum precursor, and the chemisorbed molecule 22a may include an aluminum precursor molecule.

Referring to FIG. 1I, a fourth purge gas is introduced into the chamber 1. Types and/or purge time of the fourth purge gas may be substantially the same as those of the first purge gas described with reference to FIG. 1B.

When the fourth purge gas is introduced into the chamber 1, an unreacted portion of the second oxidant can be removed from the chamber 1. Thus, a second solid-state film 26 can be formed on the first metal oxide film 20. The second solid-state film 26 may include aluminum oxide.

Referring to FIG. 1J, the processes described with reference to FIGS. 1F to 1I are repeatedly carried out at least once. As a result, a second metal oxide film 30 including multiple layers of the second solid-state film 26 is formed on the first metal oxide film 20. When the second reactant includes an aluminum precursor, the second metal oxide film 30 may include aluminum oxide.

In one example embodiment of the present invention, the second metal oxide film 30 may include aluminum oxide.

In another example embodiment of the present invention, the second metal oxide film 30 may include hafnium oxide, tantalum oxide, praseodymium oxide, lanthanum oxide, titanium oxide, etc.

Additionally, in one example embodiment of the present invention, the first metal oxide film 20 may include zirconium oxide, and the second metal oxide film 30 may include aluminum oxide.

In another example embodiment of the present invention, the first metal oxide film 20 may include BST, STO, titanium oxide, etc., and the second metal oxide film 30 may include hafnium oxide, tantalum oxide, praseodymium oxide, lanthanum oxide, titanium oxide, etc.

In an example embodiment of the present invention, the first metal oxide film 20 may have a first thickness and the second metal oxide film 30 may have a second thickness. As a result, a layer 40 may have a double-layered structure including the first and the second metal oxide films 20 and 30 sequentially formed.

When the layer 40 having the double-layered structure is employed as a dielectric layer of a capacitor, the first metal oxide film 20 may have a first thickness of about 10 Å to about 150 Å, and advantageously a first thickness of about 50 Å to about 90 Å. Furthermore, the second metal oxide film 30 may have a second thickness of about 1 Å to about 30 Å, and advantageously a second thickness of about 5 Å to about 15 Å.

According to an example embodiment of the present invention, after the preliminary metal oxide film such as a zirconium oxide film is formed on the substrate, a thermal treatment is performed on the preliminary metal oxide film to form the first metal oxide film having a dense and crystalline structure. The first metal oxide film having the dense and crystalline structure can prevent a lower structure formed beneath or below the first metal oxide film from being deteriorated or damaged while the second metal oxide film such as an aluminum oxide film is formed on the first metal oxide film.

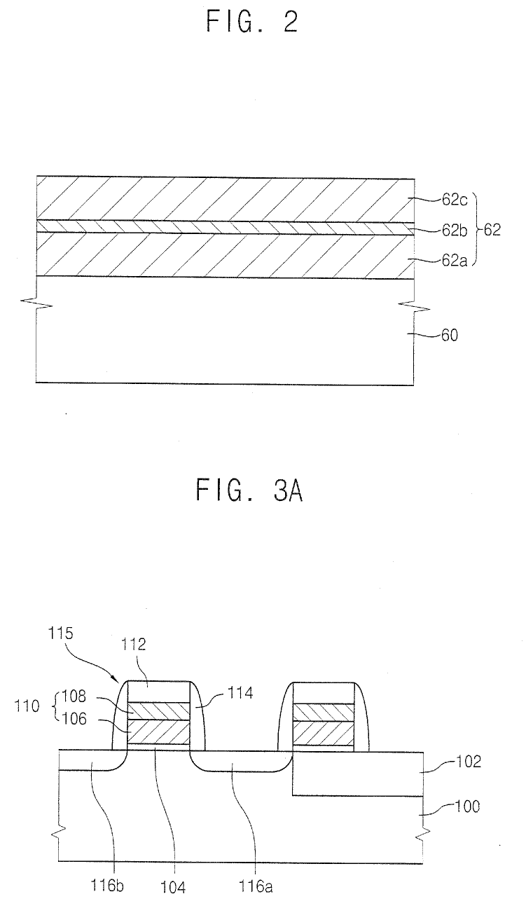

FIG. 2 is a cross-sectional view illustrating a layer formed by a method in accordance with an example embodiment of the present invention. A layer having a double-layered structure is previously described with reference to FIGS. 1A to 1J, and a layer having a triple-layered structure will be described, hereinafter.

Referring to FIG. 2, a first metal oxide film 62a is formed on a substrate 60 by performing processes substantially the same as those described with reference to FIGS. 1A to 1E. In an example embodiment of the present invention, the first metal oxide film 62a may include zirconium oxide. Furthermore, a second metal oxide film 62b is formed on the first metal oxide film 62a by performing processes substantially the same as those described with reference to FIGS. 1F to 1J. In an example embodiment of the present invention, the second metal oxide film 62b may include aluminum oxide. A third metal oxide film 62c is formed on the second metal oxide film 62b by performing processes substantially the same as those for forming the first metal oxide film 62a. In an example embodiment of the present invention, the third metal oxide film 62c may include zirconium oxide. Thus, a layer 62 including the first, the second and the third metal oxide films 62a, 62b and 62c is formed on the substrate 60.

Particularly, after a preliminary metal oxide film is formed on the substrate 60, the preliminary metal oxide film is thermally treated to form the first metal oxide film 62a having a dense and crystalline structure.

In an example embodiment of the present invention, the layer 62 may have a triple-layered structure including zirconium oxide and aluminum oxide. The first and the third metal oxide films 62a and 62c may have a dense and crystalline structure and include zirconium oxide. The second metal oxide film 62b including aluminum oxide may be interposed between the first and the third metal oxide films 62a and 62c so that the layer 62 has a sandwich structure.

When the layer 62 having the triple-layered structure is applied to a dielectric layer of a capacitor, the first metal oxide film 62a may have a thickness of about 10 Å to about 150 Å, and advantageously a thickness of about 50 Å to about 90 Å. The second metal oxide film 62b may have a thickness of about 1 Å to about 30 Å, and advantageously a thickness of about 5 Å to about 15 Å. The third metal oxide film 62c may have a thickness of about 10 Å to about 150 Å, and advantageously a thickness of about 50 Å to about 90 Å.

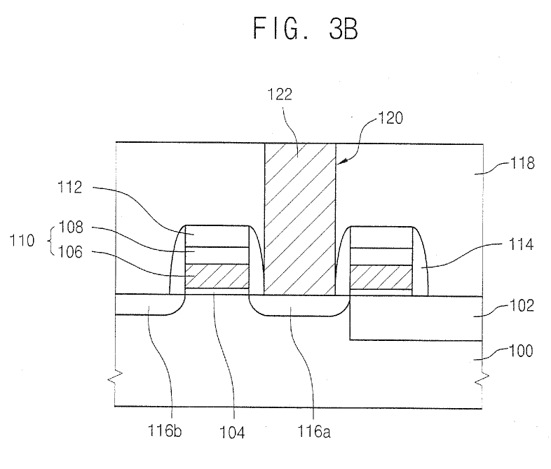

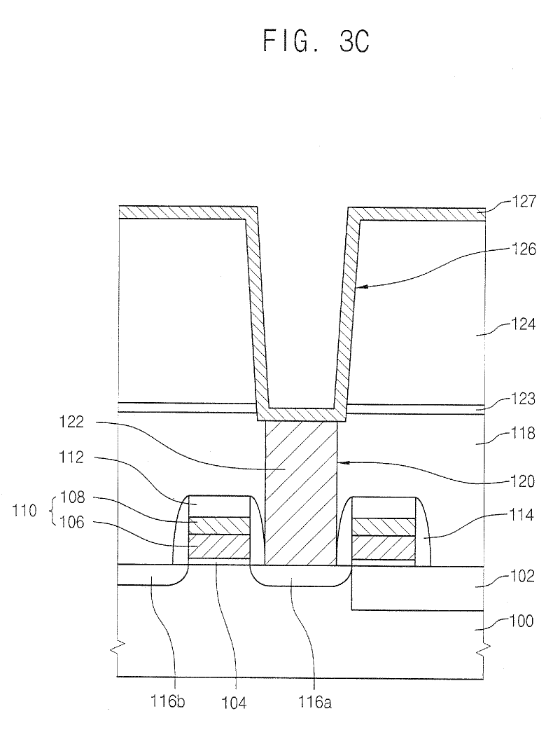

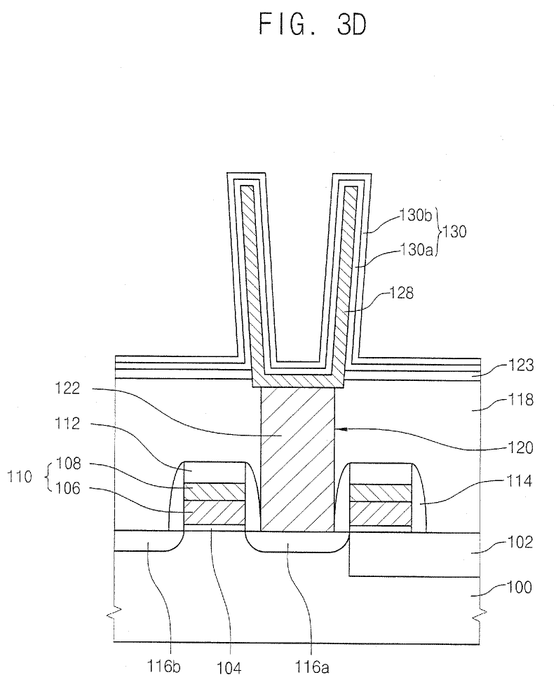

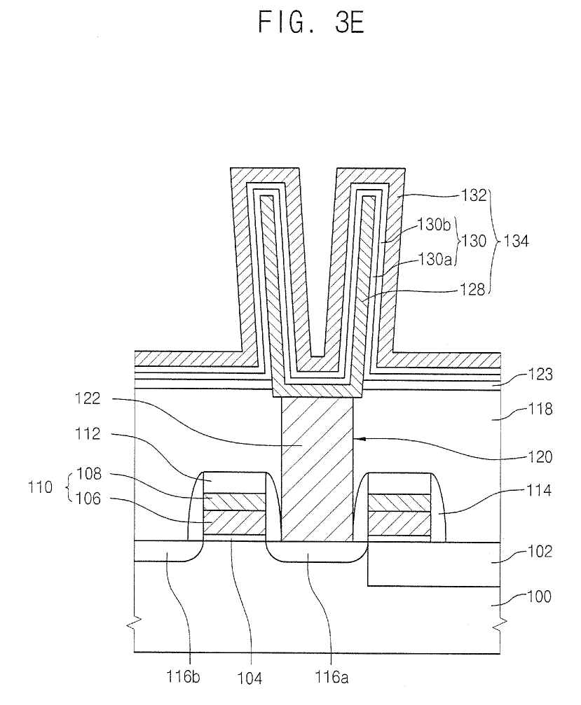

FIGS. 3A to 3E are cross-sectional views illustrating a method of manufacturing a capacitor in accordance with an example embodiment of the present invention.

Referring to FIG. 3A, an active region and a field region 102 are defined on a semiconductor substrate 100 by an isolation process. The field region 102 may be advantageously defined by a shallow trench isolation (STI) process for achieving a relatively high integration. A gate insulation layer pattern 104 and a gate conductive layer pattern 110 are formed on the semiconductor substrate 100. The gate conductive layer pattern 110 may include a polysilicon layer pattern 106 and a metal silicide layer pattern 108.

A capping insulation layer 112 is formed on the gate conductive layer pattern 110. The capping insulation layer 112 may be formed using an insulating material such as silicon oxide, silicon nitride, etc. A spacer 114 is formed on sidewalls of the gate insulation layer pattern 104, the gate conductive layer pattern 110 and the capping insulation layer 112. The spacer 114 may be formed using a silicon nitride. Thus, a gate structure 115 including the gate insulation layer pattern 104, the gate conductive layer pattern 110, the capping insulation layer 112 and the spacer 114 is formed on the semiconductor substrate 100.

Impurities are implanted into the semiconductor substrate 100 by an ion implantation process to form source/drain regions 116a and 116b in upper portions of the semiconductor substrate 100 adjacent to the gate conductive layer pattern 110. Here, the ion implantation process may be carried out before and/or after the spacer 114 is formed. The source/drain regions 116a and 116b may have a lightly doped region.

Referring to FIG. 3B, a first insulation layer is formed on the semiconductor substrate 100 to cover the gate structure 115. The first insulation layer is formed using an oxide such as boro-phosphor silicate glass (BPSG), phosphor silicate glass (PSG), undoped silicate glass (USG), spin on glass (SOG), plasma enhanced-tetraethyl orthosilicate (PE-TEOS), high-density plasma-chemical vapor deposition (HDP-CVD) oxide, etc. These materials can be used alone or in a mixture.

The first insulation layer may be patterned by a photolithography process to form a first insulation layer pattern 118 having a first opening 120 that exposes the source region 116a.

A first conductive layer is formed on the first insulation layer pattern 118 to fill up the first opening 120. The first conductive layer may be formed using doped polysilicon. The first conductive layer is planarized until an upper face of the first insulation layer pattern 118 is exposed to form a pad 122 in the first opening 120. The first conductive layer may be planarized by an etch back process, a chemical mechanical polishing (CMP) process or a combination process of etch back and CMP. The pad 122 is electrically connected to the source region 116a.

Referring to FIG. 3C, an etch stop layer 123 is formed on the pad 122 and the first insulation layer pattern 118. The etch stop layer 123 may be formed using a material having a high etching selectivity with respect to the first insulation layer pattern 118. For example, the etch stop layer 123 may be formed using silicon nitride or silicon oxynitride when the first insulation layer 118 includes oxide.

A second insulation layer is formed on the etch stop layer 123 using an oxide, and then partially etched by a photolithography process to form a second insulation layer pattern 124 on the etch stop layer 123. A portion of the etch stop layer 123 exposed by the second insulation layer pattern 124 is removed to form a second opening 126 exposing the pad 122. The second opening 126 may have a sloped sidewall, and thus a bottom portion of the second opening 126 may be substantially narrower than an upper portion thereof. This shape of the second opening 126 may be obtained in part due to a loading effect of an etch process in which an etch rate of the bottom portion may be lower than that of the upper portion of the second opening 126.

A second conductive layer 127 is formed continuously on the sidewall and the bottom portion of the second opening 126, contacting the pad 122, and on the second insulation layer pattern 124. The second conductive layer 127 will serve as a lower electrode of a capacitor. The second conductive layer 127 may be formed using a conductive material such as doped polysilicon, a metal such as ruthenium (Ru), platinum (Pt) and/or iridium (Ir), or a conductive metal nitride such as titanium nitride (TiN), tantalum nitride (TaN) and/or tungsten nitride (WN), etc. These conductive materials can be used alone or in a combination thereof.

In an example embodiment of the present invention, the second conductive layer 127 may be formed using titanium nitride.

Referring to FIG. 3D, a sacrificial layer (not shown) is formed on the second conductive layer 127. An upper portion of the sacrificial layer is then removed until an upper face of the second conductive layer 127 is exposed. An upper portion of the second conductive layer 127 positioned on the second insulation layer pattern 124 is then removed so that the second conductive layer 127 may remain on the sidewall and the bottom portion of the second opening 126. A remaining portion of the sacrificial layer is then removed from the second opening 126. Thus, the second conductive layer 127 formed on the sidewall and the bottom portion of the opening 126 may be isolated in a unit cell to form a lower electrode 128 of a capacitor. For example, the lower electrode 128 may have a trough or U-shape that includes an upper portion substantially wider than a bottom portion. In addition, the lower electrode 128 may have a height of about 10,000 Å to about 17,000 Å. Then, the second insulation pattern 124 is removed by oxide etching, thereby exposing an outer side as well as inner side of the lower electrode 128.

A dielectric layer 130 is formed on the exposed surfaces of lower electrode 128. Particularly, the dielectric layer 130 may be formed by a process substantially the same as the process described with reference to FIGS. 1A to 1J. The dielectric layer 130 includes a first metal oxide film 130a and a second metal oxide film 130b. In an example embodiment of the present invention, the dielectric layer 130 may include a zirconium oxide film and an aluminum oxide film, which are sequentially formed.

In one example embodiment of the present invention, a preliminary metal oxide film is formed on the lower electrode 128 using zirconium oxide, and then the preliminary metal oxide film is thermally treated to form the first metal oxide film 130a having a dense and crystalline structure. Thus, the lower electrode 128 may be prevented from deteriorating while the second metal oxide film 130b is formed on the first metal oxide film 130a using aluminum oxide.

In another example embodiment of the present invention, the first metal oxide film 130a may be formed using BST, STO, titanium oxide, etc., and the second metal oxide film 130b may be formed using hafnium oxide, tantalum oxide, praseodymium oxide, lanthanum oxide, titanium oxide, etc.

In one example embodiment of the present invention, the dielectric layer 130 may have a double-layered structure described with reference to FIGS. 1A to 1J. In another example embodiment of the present invention, the dielectric layer 130 may have a triple-layered structure described with reference to FIG. 2. The dielectric layer 130 having the triple-layered structure may include the first metal oxide film 130a, the second metal oxide film 130b, and a third metal oxide film (not shown).

When the dielectric layer 130 has the double-layered structure, the first and the second metal oxide films 130a and 130b may have thicknesses substantially the same as those of the first and the second metal oxide films described with reference to FIG. 1J. In addition, when the dielectric layer 130 has the triple-layered structure, the first to the third metal oxide films may have thicknesses substantially the same as those of the first to the third metal oxide films described with reference to FIG. 2.

Referring to FIG. 3E, an upper electrode 132 is formed on the dielectric layer 130. The upper electrode 132 may be formed using a conductive material that includes polysilicon, a metal such as ruthenium (Ru), platinum (Pt) and/or iridium (Ir), or a conductive metal nitride such as TiN, TaN and/or WN. These can be used alone or in a combination thereof. For example, the upper electrode 132 may be advantageously formed using titanium nitride. As a result, a capacitor 134 including the lower electrode 128, the dielectric layer 130 and the upper electrode 132 is formed over the substrate 100.

According to an example embodiment of the present invention, the dielectric layer 130 having a multi-layered structure is formed on the lower electrode 128. Particularly, the preliminary metal oxide film including zirconium oxide may be thermally treated to thereby form the first metal oxide film 130a including zirconium oxide that has a dense and crystalline structure. Thus, deterioration of the lower electrode 128 may be prevented or reduced while the second metal oxide film 130b is formed on the first metal oxide film 130a using aluminum oxide. Particularly, the first metal oxide film 130a having the dense and crystalline structure effectively prevents an oxidizing agent used for forming the second metal oxide film 130b from penetrating into the lower electrode 128.

### EXAMPLES

Evaluation of an EOT Variation According to a Thermal Treatment

Specimen 1 was prepared by sequentially forming a lower electrode, a dielectric layer having a first zirconium oxide film, an aluminum oxide film and a second zirconium oxide film, and an upper electrode on a silicon wafer. The lower and the upper electrodes were formed using titanium nitride. The dielectric layer was formed by an ALD process. The first zirconium oxide film had a thickness of about 30 Å, the aluminum oxide film had a thickness of about 5 Å, and the second zirconium oxide film had a thickness of about 60 Å.

Specimen 2 was prepared by sequentially forming a lower electrode having titanium nitride, a dielectric layer having a first zirconium oxide film, an aluminum oxide film and a second zirconium oxide film, and an upper electrode having titanium nitride on a silicon wafer. The dielectric layer was formed by an ALD process. The first zirconium oxide film had a thickness of about 45 Å, the aluminum oxide film bad a thickness of about 5 Å, and the second zirconium oxide film had a thickness of about 45 Å.

Specimen 3 was prepared by sequentially forming a lower electrode having titanium nitride, a dielectric layer having a first zirconium oxide film, an aluminum oxide film and a second zirconium oxide film, and an upper electrode having titanium nitride on a silicon wafer. The dielectric layer was formed by an ALD process. The first zirconium oxide film had a thickness of about 60 Å, the aluminum oxide film had a thickness of about 5 Å, and the second zirconium oxide film had a thickness of about 30 Å.

With respect to the specimens 1 to 3, each of the first zirconium oxide films was thermally treated under an atmosphere including nitrogen gas at a temperature of about 600° C., before the aluminum oxide film is formed on the first zirconium oxide film.

Specimens 4 to 6 were prepared. The specimen 4 was prepared by a process substantially the same as the process of forming the specimen 1 except for the thermal treatment. The specimen 5 was prepared by a process substantially the same as the process of forming the specimen 2 except for the thermal treatment. The specimen 6 was prepared by a process substantially the same as the process of forming the specimen 3 except for the thermal treatment.

A variation of an equivalent oxide thickness (EOT) of the dielectric layer according to the thermal treatment was evaluated for the specimens 1 to 6. The results are shows in a following Table 1.

TABLE 1

| | EOT | | | | |
|---|---|---|---|---|---|
| | [Å] | | EOT [Å] | | EOT [Å] |
| Specimen 1 | 9.1 | Specimen 2 | 10.4 | Specimen 3 | 9.8 |
| Specimen 4 | 11.3 | Specimen 5 | 12.0 | Specimen 6 | 10.2 |

As shown in Table 1, the specimens 1 to 3 in which the first zirconium oxide films were thermally treated, have EOTs substantially thinner than those of the specimens 4 to 6 in which the first zirconium oxide films were not thermally treated. The EOTs were reduced by a range of about 0.4 Å to about 2.2 Å after performing the thermal treatment. A decrease of EOT may mean a densification or a crystallization of the first zirconium oxide film. Accordingly, it may be confirmed that the first zirconium oxide film formed by the thermal treatment may have a dense and crystalline structure.

Evaluation of Leakage Current Characteristics of a Capacitor According to a Thermal Treatment

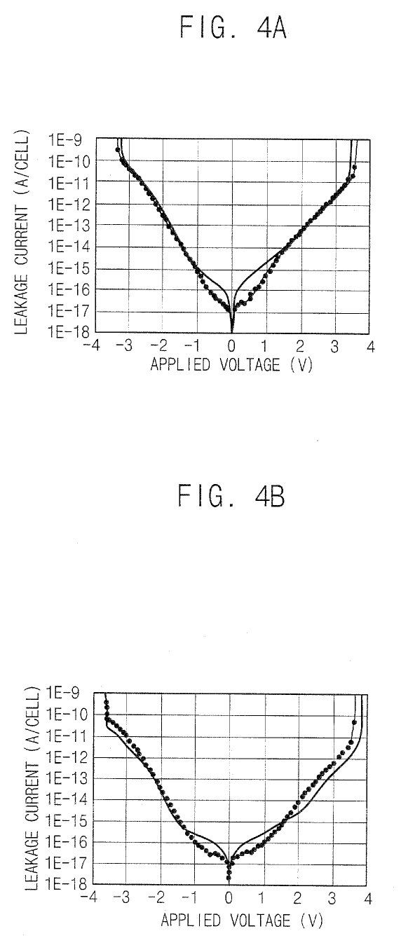

FIGS. 4A and 4B are graphs showing leakage current characteristics of a capacitor of a semiconductor device manufactured by a method in an example embodiment of the present invention.

A first capacitor including a lower electrode having titanium nitride, a dielectric layer and an upper electrode having titanium nitride was prepared. The dielectric layer of the first capacitor included a zirconium oxide film having a thickness of about 55 Å and an aluminum oxide film having a thickness of about 10 Å. A second capacitor including a lower electrode having titanium nitride, a dielectric layer and an upper electrode having titanium nitride was prepared. The dielectric layer of the second capacitor included a zirconium oxide film having a thickness of about 70 Å and an aluminum oxide film having a thickness of about 10 Å. A third capacitor including a lower electrode having titanium nitride, a dielectric layer and an upper electrode having titanium nitride was prepared. The dielectric layer of the third capacitor included a zirconium oxide film having a thickness of about 90 Å and an aluminum oxide film having a thickness of about 7 Å.

Each of the zirconium oxide films was thermally treated under an atmosphere including nitrogen gas at a temperature of about 500° C. before the aluminum oxide film was formed on the zirconium oxide film.

Leakage currents of the capacitors were measured before and after the thermal treatment on the zirconium oxide films. As shown in FIGS. 4A and 4B, the thermal treatment enhanced a voltage of about 0.3V at a leakage current of about 1 fA/cell in the same EOT condition.

Therefore, it may be noted that the zirconium oxide film having a dense and crystalline structure that is obtained by the thermal treatment, may sufficiently prevent an oxidizing agent from penetrating into the lower electrode while the aluminum oxide film is formed on the zirconium oxide film by a high temperature oxidation process. As a result, leakage current characteristics of the capacitor may be improved and an EOT of the dielectric layer may be reduced.

According to the present invention, a dielectric layer having a multi-layered structure may be formed using a thermal treatment. Particularly, a zirconium oxide film having a dense and crystalline structure may be formed by the thermal treatment. Therefore, a deterioration of a lower electrode positioned under the dielectric layer may be prevented or reduced, and a generation of a leakage current from the dielectric layer may be suppressed. Furthermore, the dielectric layer having a sufficiently thin EOT may be formed by the thermal treatment to enhance an integration degree of a semiconductor device.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific example embodiments of the present invention disclosed, and that modifications to the disclosed example embodiments, as well as other embodiments, are intended to be included within the scope of the appended claims. The present invention is defined by the following claims, with equivalents of the claims to be included therein.

What is claimed is:

1. A method of forming a layer comprising:
forming a preliminary zirconium oxide film on a substrate by introducing a first reactant including a zirconium precursor, and a first oxidant onto the substrate;
performing a thermal treatment on the preliminary zirconium oxide film to form a first zirconium oxide film having a dense and crystalline structure; and
forming an aluminum oxide film on the first zirconium oxide film by introducing a second reactant including an aluminum precursor, and a second oxidant onto the substrate.

2. The method of claim 1, wherein the thermal treatment is performed at a temperature of about 400° C. to about 700° C. in an atmosphere including an inactive gas, an oxygen gas or a combination thereof.

3. The method of claim 1, wherein the first reactant comprises tetrakis (ethylmethylamino) zirconium, zirconium butyl oxide or a mixture thereof.

4. The method of claim 1, wherein the second reactant comprises trimethyl aluminum, aluminum butyl oxide, or a mixture thereof.

5. The method of claim 1, wherein each of the first and the second oxidants comprises at least one oxidant selected from the group consisting of ozone, oxygen, water vapor, hydrogen peroxide, oxygen plasma, oxygen remote plasma, nitrous oxide, nitrous oxide plasma, methanol and ethanol.

6. The method of claim 1, wherein the preliminary zirconium oxide film and the aluminum oxide film are formed by an atomic layer deposition (ALD) process respectively.

7. The method of claim 1, further comprising forming a second zirconium oxide film on the aluminum oxide film by introducing a third reactant including a zirconium precursor, and a third oxidant onto the substrate.

8. The method of claim 7, wherein the second zirconium oxide film is formed by an ALD process.

9. A method of manufacturing a capacitor comprising:
forming a lower electrode on a substrate;
forming a dielectric layer having a multi-layered structure on the lower electrode, the dielectric layer including a first zirconium oxide film having a dense and crystalline structure and an aluminum oxide film formed on the first zirconium oxide film; and
forming an upper electrode on the dielectric layer,
wherein forming the dielectric layer comprises:
forming a preliminary zirconium oxide film on the lower electrode by introducing a first reactant including a zirconium precursor, and a first oxidant onto the lower electrode;
performing a thermal treatment on the preliminary zirconium oxide film to form the first zirconium oxide film having the dense and crystalline structure; and
forming the aluminum oxide film on the first zirconium oxide film by introducing a second reactant including an aluminum precursor, and a second oxidant onto the substrate.

10. The method of claim 9, wherein each of the lower electrode and the upper electrode comprises at least one selected form the group consisting of polysilicon, a metal and a metal nitride.

11. The method of claim 9, wherein the thermal treatment is performed at a temperature of about 400° C. to about 700° C. under an atmosphere including an inactive gas, an oxygen gas or a combination thereof.

12. The method of claim 9, wherein the first reactant comprises tetrakis (ethylmethylamino) zirconium, zirconium butyl oxide or a mixture thereof, the second reactant comprises trimethyl aluminum, aluminum butyl oxide or a mixture thereof, and each of the first and the second oxidants comprises at least one oxidant selected from the group consisting of ozone, oxygen, water vapor, hydrogen peroxide, oxygen plasma, oxygen remote plasma, nitrous oxide, nitrous oxide plasma, methanol and ethanol.

13. The method of claim 9, wherein the preliminary zirconium oxide film and the aluminum oxide film are formed by an ALD process, respectively.

14. The method of claim 13, wherein the preliminary zirconium oxide film has a thickness of about 10 Å to about 150 Å, and the aluminum oxide film has a thickness of about 1 Å to about 30 Å.

15. The method of claim 9, wherein forming the dielectric layer further comprises forming a second zirconium oxide film on the aluminum oxide film by introducing a third reactant including a zirconium precursor, and a third oxidant onto the substrate.

16. The method of claim 15, wherein the second zirconium oxide film is formed by an ALD process.

17. The method of claim 15, wherein the second zirconium oxide film has a thickness of about 10 Å to about 150 Å.

18. A method of forming a layer comprising:
forming a preliminary metal oxide film on a substrate by introducing a first reactant including a first metal precursor, and a first oxidant onto the substrate;
performing a thermal treatment on the preliminary metal oxide film to form a first metal oxide film having a dense and crystalline structure; and
forming a second metal oxide film on the first metal oxide film by introducing a second reactant including a second metal precursor, and a second oxidant onto the substrate.

19. The method of claim 18, wherein the first and the second metal oxide films comprises a metal oxide different from each other, and the metal oxide comprises any one selected from the group consisting of zirconium oxide, aluminum oxide, barium strontium oxide, strontium oxide, hafnium oxide, tantalum oxide, praseodymium oxide, titanium oxide and lanthanum oxide.

20. The method of claim 18, wherein the thermal treatment is performed at a temperature of about 400° C. to about 700° C. under an atmosphere including an inactive gas, an oxygen gas or a combination thereof.
